(19) United States
(12) Patent Application Publication
(10) Pub. No.: US 2007/0052057 A1
(43) Pub. Date: Mar. 8, 2007

(54) Method and Schottky diode structure for avoiding intrinsic NPM transistor operation

(75) Inventor: Vladimir F. Drobny, Tucson, AZ (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/497,056

(22) Filed: Aug. 1, 2006

Related U.S. Application Data
(60) Provisional application No. 60/714,752, filed on Sep. 7, 2005.

(51) Int. Cl. H01L 31/07

(52) U.S. Cl. 257/471

(57) ABSTRACT

A Schottky diode includes an isolation region of a first conductivity type and an anode region of a second conductivity type isolated by the isolation region, the anode region including a lightly doped deep anode region of the second conductivity type and an increased dopant region of the second conductivity type, the increased dopant region including a shallow surface dopant spike region of the second conductivity type at a surface of the anode region. A heavily doped anode contact region of the second conductivity type electrically contacts the anode region, and a metal silicide cathode region is disposed in the surface dopant spike region. The peak dopant surface concentration is high enough to produce a predetermined saturation current density. The dopant concentration in the increased dopant region is sufficiently high to suppress the current gain of a parasitic bipolar transistor enough to adequately suppress operation of the parasitic bipolar transistor.

### CROSS REFERENCE TO RELATED APPLICATION

This application claims the benefit of prior filed co-pending U.S. provisional application Ser. No. 60/714,752 filed Sep. 7, 2005, entitled “High reverse current leakage in A03 RFID Schottky barrier diodes”, by Vladimir F. Drobny, and incorporated herein by reference.

### BACKGROUND OF THE INVENTION

The present invention relates generally to integrated circuit Schottky barrier diodes, and more particularly to Schottky barrier diode structures and methods which avoid intrinsic bipolar transistor operation of the regions involved in the formation of the Schottky barrier diodes.

One application of Schottky barrier diodes (hereinafter simply “Schottky diodes”) is in the manufacture of passive RFID tag chips (i.e., radio frequency identification tag chips), which have no available battery for operating power. An RFID tag chip generates its own power by detecting and rectifying an RF signal transmitted by a nearby RFID reader. The detecting and rectifying of a relatively weak RF signal is accomplished by using a Schottky barrier diode having a very low barrier height Φ_{B}. The Schottky diodes need to have a certain barrier height Φ_{B}, because for RFID tag applications a certain distance range is specified within which the Schottky diode must be able to detect and rectify the RF signal, which weakens with the distance from which it is transmitted by the RFID tag reader. The rectified RF signal is a DC signal which is instantly used to provide the operating power required by the RFID chip. The RFID tag chip is a complex integrated circuit, which is able to manipulate and store RFID data, and which also functions both as a receiver and a transmitter. It includes a small antenna to receive enough of the RF power transmitted by the RFID tag reader that the Schottky diode can detect and rectify the received is RF power to generate sufficient DC power allowing the RFID tag chip to instantly begin its operation as a receiver, transmitter, and RFID data processor.

In order for the Schottky diode to rectify the weak RF signal received by the antenna within the specified range, the Schottky diode needs to have a very low turn on voltage, or high saturation current density (J_{S}), which is achieved by a low Schottky barrier height (Φ_{B}) junction. The Schottky diodes used in RFID tag applications also need to have low series resistance R_{S} and low active junction (Schottky Junction) and related device-isolation related parasitic capacitances.

So-called NPM (i.e., N—P-Metal) transistors and PNM (P—N-Metal ) bipolar junction transistors (BJT), typically having metal silicide collectors, have been previously known. Kumar and Rao reported on characteristics wherein a PtSi Schottky barrier diode functions in the same way as a P-type doped collector would function in a PNP transistor. See M. J. Kumar and D. V. Rao, “A new Lateral PNM Schottky Collector Bipolar Tranistor (SCBT) on SOI for Nonsaturating VLSI Logic Design”, IEEE Transactions on Electron Devices, vol. 49, no. 6, pp. 1070-1072, (2002). PNM devices with a metal silicide collector also were reported previously in S. Akbar, S. Ratanaphanyarat, J. B. Kuang, S. F. Chu, and C. M. Hsieh, “Schottky Collector Vertical PNM Bipolar Transistor,” Electronics Letters, vol. 28, no. 1, pp. 86-87, (Jan. 2, 1992).

The foregoing prior art focuses on enhancing the functionality and operation of desired NPM and PNM devices as bipolar transistors, wherein the silicon base-collector junction regions are silicon base-metal silicide junction regions. This is opposed to the subsequently described present invention wherein the Schottky barrier diodes are the desired devices and the intrinsic NPM or PNM bipolar junction transistors are parasitic devices. Since these parasitic devices can contribute significant amount of the total undesired reverse current leakage of the Schottky barrier diode, which is the primary and desired device, it is an objective to prevent these parasitic transistors from functioning. Note that these parasitic NPM or PNM devices can be readily formed in deep submicron CMOS devices. The deep submicron CMOS “wells” act as thin PNM base regions having very low integrated dopant, which is referred to commonly as a base Gummel number (in the physics of bipolar junction transistors). As the base and the base Gummel number become smaller the gain and thus the undesired effectiveness of these parasitic devices becomes larger. Every reduction in the line widths, e.g., 90 nanometers, 65 nanometers, 45 nanometers etc., of successively developed CMOS technologies results in devices which will be increasingly more vulnarable to the above described parasitic leakage. Note that Schottky barrier diodes formed in technologies having large CMOS devices have much deeper CMOS “wells” and therefore do not generally suffer diode leakage caused by the above described parasitic devices.

In integrated circuits, including deep submicron CMOS integrated circuits, there are many potential applications for Schottky diodes, but for various reasons they have not been used much. So far, the Schottky barrier diodes have mostly been used in bipolar integrated circuit processes which have included conventional buried layer structures, and have been used very little in CMOS integrated circuits. (The term “deep submicron” refers to integrated circuit processing technologies in which the minimum line widths and line spacings are less than 0.25 micrometers, i.e., 250 nanometers.) In a majority of applications, it would be desirable for Schottky diodes to have low (1×10¹⁴ atoms per cubic centimeter) to moderate (1×10⁷ atoms per cubic centimeter) anode or cathode doping concentrations and high barrier height Φ_{B}.

Thus, there is an unmet need for an integrated circuit Schottky barrier diode structure and method that can be designed to avoid undesired functionality of parasitic intrinsic bipolar transistor structures formed by the elements used in formation of the Schottky barrier diode structure.

### SUMMARY OF THE INVENTION

It is an object of the invention to provide an integrated circuit Schottky barrier diode structure and method that avoid undesired operation of intrinsic bipolar transistor structures formed by elements used in formation of the Schottky barrier diode structure.

It is another object of the invention to provide an integrated circuit Schottky barrier diode structure and method using CMOS technology which provides decreased line widths and feature sizes and also avoids undesired operation of intrinsic bipolar transistor structures formed by elements used in formation of the Schottky barrier diode structure.

Briefly described, and in accordance with one embodiment, the present invention provides a Schottky diode includes an isolation region (16) of a first conductivity type (e.g., N) and an anode region (18) of a second conductivity type isolated by the isolation region, the anode region (18) including a lightly doped deep anode region (18A) of the second conductivity type (e.g., P) and an increased dopant region (25) of the second conductivity type (P), the increased dopant region (25) including a shallow surface dopant spike region (24) of the second conductivity type (P) at a surface of the anode region (18). A heavily doped anode contact region (20A,B) of the second conductivity type electrically contacts the anode region (18), and a metal silicide cathode region (22A,B) is disposed in the surface dopant spike region. The peak dopant surface concentration is high enough to produce a predetermined saturation current density. The dopant concentration in the increased dopant region is sufficiently high to suppress the current gain of a parasitic bipolar transistor (T1,2 . . . n) enough to adequately suppress operation of the parasitic bipolar transistor.

In one embodiment, the invention provides a Schottky diode (10A) including an isolation region (16) of a first conductivity type (e.g., N), an anode region (18) of a second conductivity type (e.g., P) isolated by the isolation region (16), the anode region (18) including a relatively lightly doped deep anode region (18A) of the second conductivity type (P) and an increased dopant region (25) of the second conductivity type (P), the increased dopant region (25) including a shallow surface dopant spike region (24) of the second conductivity type (P) at a surface (15) of the anode region (18), the increased dopant region (25), including the shallow surface dopant spike region (24), being more heavily doped than the deep anode region (18A). A heavily doped anode contact region (20A,B) of the second conductivity type (P+) is disposed at the surface of the anode region (18), and a metal silicide cathode region (22A,B) is disposed at the surface of the anode region (18) within the surface dopant spike region. The surface dopant spike region (24) has a sufficiently high peak dopant concentration to provide a saturation current density that has at least a first predetermined value, wherein the increased dopant region (25) of the anode region (18) has a sufficiently high dopant concentration to cause the current gain of a parasitic bipolar transistor (T1,2 . . . n) to be less than a second predetermined value and to cause a series resistance to have at least a third predetermined value, the isolation region (16), the anode region (18), and the metal silicide cathode region (22A) form an emitter, a base, and a collector, respectively, of the parasitic bipolar transistor. The increased dopant region (25) has a dopant concentration sufficiently high to reduce the current gain of the parasitic bipolar transistor enough to cause collector current of the parasitic bipolar transistor to be less than a predetermined proportion of a reverse current (I_{R}) of the Schottky diode if the isolation region (16) is at the same potential as the anode region (18). A metal silicide anode contact region (19A) is disposed in the heavily doped anode contact region (20A).

In the described embodiments, the increased dopant region (25) extends from the surface of the anode region (18) approximately 1 micron into the anode region (18) to the deep anode region (18A), wherein the surface dopant spike region (24) extends from the surface of the anode region (18) approximately 1000 angstroms units into the increased dopant region (25). The metal silicide is cobalt silicide.

In one embodiment, the invention provides a method of forming an integrated circuit Schottky diode (10A) including forming an isolation region (16) of a first conductivity type (e.g., N), forming an anode region (18) of a second conductivity type (e.g., P), the anode region (18) being isolated by the isolation region (16), forming an increased dopant region (25) in the anode region (18), the increased dopant region (25) including a shallow surface dopant spike region (24) of the second conductivity type (P) at a surface of the anode region (18), forming a heavily doped anode contact region (20A,B) of the second conductivity type (P+) at the surface of the anode region (18), and forming a metal silicide cathode region (22A,B) disposed in the increased dopant region(25) at the surface of the anode region (18), wherein the shallow surface dopant spike region (24) of the anode region (18) has a peak dopant concentration that provides a saturation current density that has at least a first predetermined value, and wherein the dopant concentration in the increased dopant region (25) causes the current gain of a parasitic bipolar transistor (T1,2 . . . n) to be less than a predetermined value to suppress operation of the parasitic bipolar transistor, wherein the isolation region (16), the anode region (18), and the metal silicide cathode region (22A) form an emitter, a base, and a collector of the parasitic bipolar transistor. The increased dopant region (25) is formed with a sufficiently high dopant concentration to provide a series resistance that has at least a second predetermined value and a reverse current density that is less than a third predetermined value.

In one embodiment, the invention provides a Schottky diode (10A) including an isolation region (16) of a first conductivity type (e.g., N), an anode region (18) of a second conductivity type (e.g., P) isolated by the isolation region (16), the anode region (18) including a lightly doped deep anode region (18A) of the second conductivity type (P) and an increased dopant region (25) of the second conductivity type (P), the increased dopant region (25) including a shallow surface dopant spike region (24) of the second conductivity type (P) at a surface of the anode region (18), a heavily doped anode contact region (20A,B) of the second conductivity type (P+) at the surface (15) of the anode region (18), a metal silicide cathode region (22A,B) disposed in the surface dopant spike region (24) at the surface of the anode region (18), and means for providing the shallow surface dopant spike region (24) of the anode region (18) with a peak dopant concentration that provides a saturation current density that has at least a first predetermined value, and means for providing the dopant concentration in the increased dopant region (25) so as to cause the current gain of a parasitic bipolar transistor (T1,2 . . . n) to be less than a predetermined value to suppress operation of the parasitic bipolar transistor, the isolation region (16), the anode region (18), and the metal silicide cathode region (22A) forming an emitter, a base, and a collector of the parasitic bipolar transistor.

### BRIEF DESCRIPTION OF THE DRAWINGS

FIG. 1A is a cross sectional diagram of a integrated circuit junction isolated lateral unguarded Schottky barrier diode including an intrinsic NPM parasitic bipolar transistor, including a surface dopant spike region 24.

FIG. 1B is a cross sectional diagram of a integrated circuit junction isolated lateral unguarded Schottky barrier diode including an intrinsic NPM parasitic bipolar transistor, including a “flat” high dopant concentration region 25 which includes a surface dopant spike region 24.

FIG. 2A shows a simulated example of a Schottky diode anode concentration profile for a “spike” dopant distribution.

FIG. 2B shows a simulated example of a Schottky diode anode concentration profile for a relatively flat increased dopant distribution region 25.

FIG. 3 is a graph illustrating forward and reverse current-voltage characteristics for a Schottky barrier diode with a surface dopant spike distribution at the anode surface and also for a Schottky barrier diode with a uniform dopant distribution.

FIG. 4 is a graph illustrating the current-voltage characteristic of a Schottky diode having an electrically floating N-well region and also of a Schottky diode having a N-well region connected to its anode.

FIG. 5A is a cross sectional diagram of a junction-isolated, lateral, unguarded Schottky barrier diode with an anode dopant spike profile essentially identical to the anode dopant spike profile in FIG. 1A and further illustrating the presence of an intrinsic parasitic NPM transistor.

FIG. 5B is a cross sectional diagram of a junction-isolated, lateral, unguarded Schottky barrier diode with a “flat” anode dopant profile essentially identical to the “flat” anode dopant profile in FIG. 1B and further illustrating the presence of an intrinsic parasitic NPM transistor.

FIG. 6 is a graph illustrating the forward and reverse current-voltage characteristics of a Schottky diode having a floating N-well region connected to its anode.

FIG. 7 is a graph illustrating the forward current-voltage characteristic of a Schottky diode biased as a bipolar transistor for Gummel Plot types of measurements, with a N-well region connected to its anode.

FIG. 8 is a cross sectional diagram of a integrated circuit junction isolated lateral unguarded Schottky barrier diode similar to the one shown in FIG. 1A but with the conductivity types of the N-type and P-type regions reversed.

FIG. 9 is a cross sectional diagram of a integrated circuit junction-isolated lateral unguarded Schottky barrier diode essentially identical to the one shown in FIG. 8 and further showing an intrinsic PNM parasitic transistor.

### DETAILED DESCRIPTION OF THE PREFERRED EMBODIMENTS

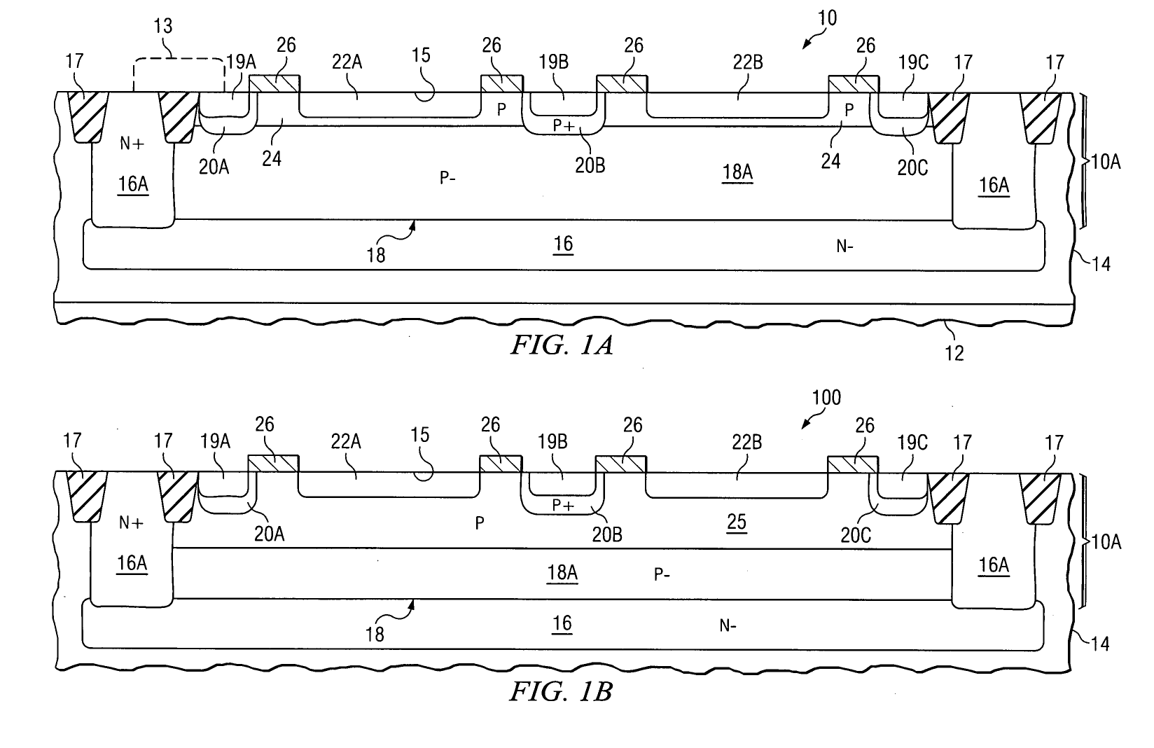

Referring to FIG. 1A, integrated circuit lateral Schottky diode structure 10 includes a lightly doped P-type region 14 formed on a wafer substrate 12. A lightly doped N-type well region 16 is formed in P-type region 14, which can be, but does not need to be, an epitaxial silicon layer formed on a wafer 12. After formation of a deep N-well region using a very high energy (MeV) implantation, a lightly doped P-type region 18, including a deep “bulk” portion thereof, remains over the buried—well region 16. A closed N+ sidewall isolation region 16A surrounds the sides of P-type region 18 and extends downward from the upper surface of integrated circuit structure 10 into the upper surface of N-well region 16. A STI (shallow trench region isolation) trench 17 is formed along the inner and outer upper surface edges of closed N+ sidewall isolation region 16A. The P− anode bulk region 18A forms an anode region of a lateral Schottky diode 10A. The P+ anode contact regions 20A, 20B and 20C are sections of the same anode contact region formed in the upper surface of the P-type anode region 18. A shallow “surface dopant spike region” 24 is formed in the upper 1000 microns or so immediately beneath the surface 15 of the P-type anode region 18.

Metal silicide regions 19A, 19B and 19C are formed in anode contact regions 20A, 20B and 20C, respectively, and are sections of the same metal silicide region for contacting the P-type anode region 18 through P+ anode contact regions 20A,B,C. Metal silicide regions 22A,B are parts of the same metal silicide cathode region and are formed within the surface dopant spike region 24 and constitute the cathode of Schottky diode 10A. The metal silicide regions in FIG. 1A can be formed of, for example, cobalt silicide (CoSi₂). Reference numerals 26 designate silicon oxide or silicon nitride insulator (or any other suitable insulator) over the portions of surface dopant spike region 24 that are located between the anode contact structures such as 20A and the adjacent cathode structures such as 22A of Schottky diode 10A.

Dashed line 13 designates a conductive means that may be used to electrically connect N-well 16 and N+ isolation region 16A to anode 18 through the P+ anode contact regions 20A,B,C.

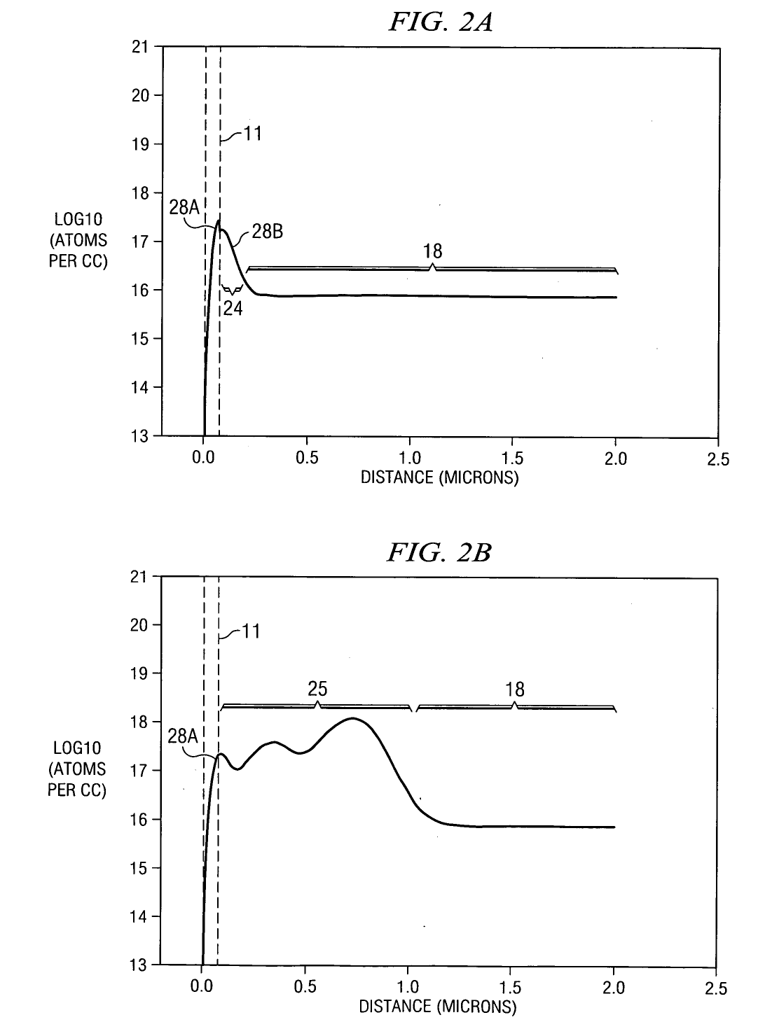

FIG. 1B shows the same structure as FIG. 1A except that a P-type “increased dopant region” 25 extends downward approximately 1 micron into anode bulk region 18A from the upper surface 15 of P-type anode region 18. The dopant concentration profile present in increased dopant region 25 and FIG. 1B is the increased “flat” portion 25 of the dopant concentration profile shown in FIG. 2B. It is to be understood that the increased “flat” portion 25 of the doping concentration profile in FIG. 2B can be thought of as also including surface dopant spike region 24 of FIG. 1B, although for convenience this is not illustrated in FIG. 1B.

FIG. 2A shows a simulated doping concentration profile of anode region 18, including a shallow, approximately 1000 angstrom deep, surface dopant spike region 24, with peak dopant concentration of approximately 2×10¹⁷ atoms per cubic centimeter, and with a relatively uniform dopant concentration level of approximately 1×10¹⁶ atoms per cubic centimeter in the deeper “bulk” portion 18A of anode region 18. (The region 11 between the parallel vertical dashed lines corresponds to a thin oxide layer, and the curve section 28A in region 11 corresponds to dopant concentration in the thin oxide layer 11. The oxide layer 11 is eventually removed during the integrated circuit processing.)

FIG. 2B shows an example of a relatively flat doping concentration profile in the roughly 1 micron deep “increased dopant region” 25 immediately under the upper surface 15, in contrast to the doping concentration profile of the surface dopant spike region 24 in FIG. 2A, both having a roughly “flat” surface concentration of approximately 2×10¹⁷ atoms per cubic centimeter.

Schottky diode 10A needs to have a certain relatively low barrier height (Φ_{B}) for RFID tag applications in order to provide an adequate range of distances within which the Schottky diode can produce the required DC operating power by detection of the RF signal transmitted by the interrogating RFID tag reader (not shown). As previously mentioned, an RFID tag chip is a complex integrated circuit with many logic and signal processing functions and also functions both as a receiver and a transmitter and requires power derived from the detected and rectified transmitted RF signal as its sole source of operating power.

For Schottky diode 10A as shown in FIG. 1A to operate correctly for the above mentioned RFID applications, it needs to be optimized so as to have sufficiently low forward series resistance R_{S}, low junction capacitance Cj (which limits the physical size of the Schottky diode), and sufficiently high forward saturation current density J_{S} (which is another measure of the barrier height). The lower the barrier height Φ_{B} the higher the saturation current density J_{S} will be. The lower the RC time constant of the series resistance R_{S} and the capacitance Cj associated with the Schottky diode junction, the more sensitive the RFID tag chip is to the transmitted RF signal.

This means that in order for the RFID tag chip to be interrogated from a greater distance by the RFID reader, the integrated circuit Schottky diode needs to have a low barrier height Φ_{B}, low series resistance R_{S}, and low junction capacitance Cj (including the isolation capacitance associated with the Schottky diode P-to-Metal junction). As a practical matter, the Schottky diode junction area must be no larger than a certain amount, and since the amount of forward saturation current I_{S} has to be high enough, in accordance with a specification depending upon the total current consumption of the RFID tag circuit, its barrier height Φ_{B} must be accordingly low. However, too low of a barrier height Φ_{B} can result in too high of a reverse current I_{R}, which is also undesirable.

Ordinarily, when the saturation current I_{S} of Schottky diode 10A is high, its reverse current I_{R} also is high. This is undesirable in an RFID tag chip, because what is preferable or needed is a high saturation current I_{S} and a low reverse current I_{R}. By providing an adequately high doping concentration in surface dopant spike region 24 and an adequately low bulk doping concentration in the deep bulk portion 18A of anode region 18, the needed level of saturation current in Schottky diode 10A is obtained without causing a large increase in the reverse junction current I_{R} as a function of the reverse voltage V_{R}.

For example, considering the total power requirements of the RFID tag chip and its required detection range distance, the maximum total circuit diode junction capacitance was limited to Cj=0.18 picofarads and the saturation current density J_{S}=2 micromperes per square micrometer. To meet these values a very low barrier height of Φ_{B}<0.42 eV was required. Because of the intrinsic barrier height of the CoSi₂ to N-doped silicon interface, Φ_{B0n}=0.64 eV, a P− substrate has to be used in order to lower the intrinsic barrier height to Φ_{B0p}=0.48 eV, based on the relationships
Φ_{B0n}+Φ_{B0p}=E_{G(Si)}=1.12 eV Equation 1
and
Φ_{B}=Φ_{B0}−ΔΦ_{B}, Equation 2
where Φ_{B0n} and Φ_{B0p} are the intrinsic barrier heights of silicide to N-type and P-type doped silicon, respectively, and eV means electron volts.

Additional barrier height lowering is achieved by increasing the electric field at the silicon/silicide junction according to the relationship

$$Δ {Φ}_{B} = α E + \sqrt{\frac{qE}{4 π ɛ}} , \qquad Equation 3$$

where ΔΦ_{B} is the barrier height lowering term, E is the electric field at the silicide/silicon interface, and α is the diode junction tunneling coefficient. In a lateral diode the carrier transport is dominated at the silicide/silicon junction edge where the electric field and thus also ΔΦ_{B} are increased by the silicide/silicon junction curvature. The relationship between J_{S} and the Schottky barrier height can be written as

$${J}_{S} = A ** {T}^{2} exp ( - \frac{q ( {Φ}_{B 0} - {ΔΦ}_{B} )}{kT} ) , \qquad Equation 4$$

where k is the Boltzman constant, T is the absolute temperature and A** is the Richardson constant. (The applied voltage across the Schottky diode in the forward biased direction is V_{F} and in the reverse biased direction it is V_{R}, but these terms do not appear in Equation 4 because the saturation current density J_{S} occurs when the junction bias is equal to zero.)

The electric field E at the silicon/silicide interface of the anode region 18 is a strong function of the dopant concentration thereat. The dopant concentration profile with a surface dopant spike region 24 as illustrated in FIG. 2A affects the electric field and the barrier height lowering term ΔΦ_{B} and thus the saturation current density J_{S} at the near-zero and very low bias voltages as required by the RFID application. The dopant concentration profile also affects the diode series resistance R_{S}. The type of dopant concentration profile as illustrated in FIG. 2B in increased dopant region 25 influences the diode series resistance R_{S} and the barrier height lowering term ΔΦ_{B} and thus the reverse current I_{R} at high reverse voltages. To summarize, it is clear that an increase in the doping concentration at the silicon/silicide interface of the anode region 24 increases the saturation current density J_{S} near zero and very low reverse bias voltages only. An increase in the dopant concentration and its distribution in the deep bulk portion 1A of anode region 18 increases the barrier height lowering term ΔΦ_{B} and thus the saturation current density J_{S}, and J_{R} at higher reverse voltages and also further lowers the series resistance R_{S} of the Schottky diode 10A.

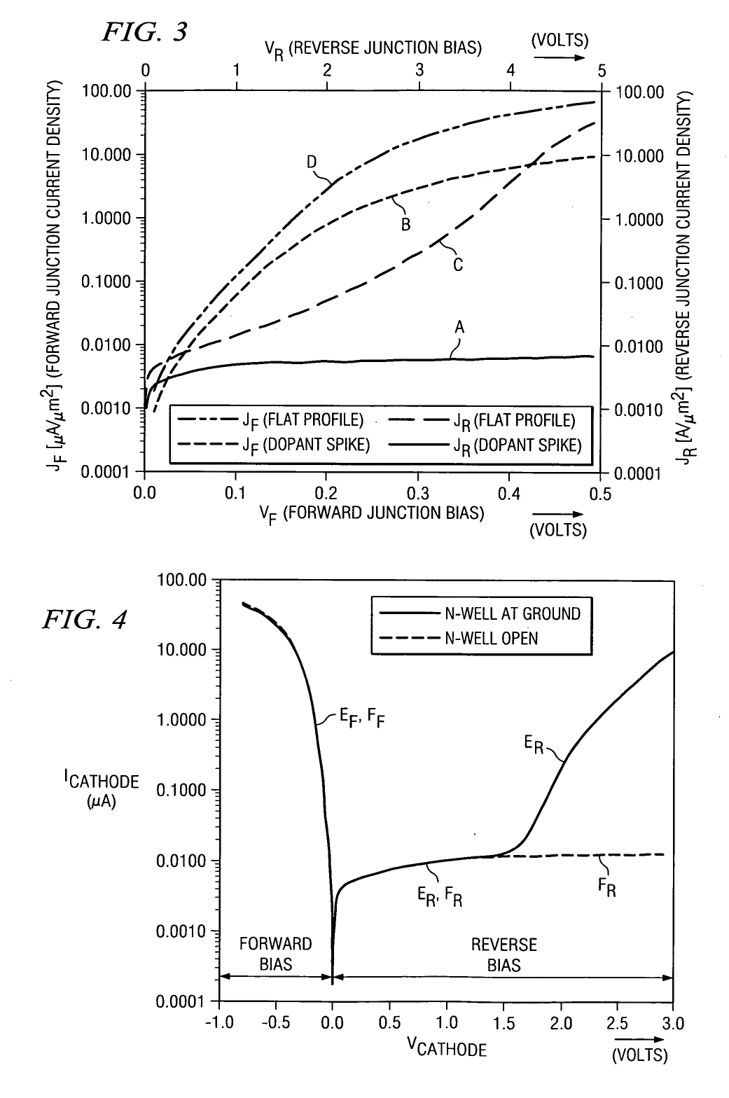

FIG. 3 shows the forward and reverse current-voltage characteristics of Schottky diode 10A both with and without the presence of surface dopant spike region 24, and with and without the presence of increased dopant region 25 (when the isolation region, including N-well 16 and N+ side isolation wall 16A) is electrically floating. With surface dopant spike 24 present, the extrapolated Y-intercept of the forward current curve B corresponds to the saturation current density J_{S}. Using the additional doping in increased dopant region 25 as illustrated in FIG. 2B, slightly increases the dopant concentration at the anode surface from 2×10¹⁷ atoms per cubic centimeter to 3×10¹⁷ atoms or more per cubic centimeter, thus increasing J_{S} slightly as illustrated by the forward bias current curve D. (The legend “FLAT PROFILE” in FIG. 3 corresponds to the anode dopant concentration profile of FIG. 2B used in anode region 18 in FIG. 1B, and the legend “DOPANT SPIKE” in FIG. 3 corresponds to the anode dopant concentration profile is used in anode region 18 in FIG. 1A. The dopant concentration increases much more dramatically deeper in the anode region from 0.1 micrometer (1000 angstroms) below surface 15 to 1 micrometer below surface 15, from 1×10¹⁷ atoms per cubic centimeter to greater than 5×10¹⁷ atoms per cubic centimeter as shown in FIG. 2B. As a result, the barrier height lowering term ΔΦ_{B} near zero voltage bias increases only slightly, but increases much more rapidly at higher reverse bias voltages. Note that this reduces the barrier height according to Φ_{B}−ΔΦ_{B}.

In FIG. 3, using a high doping concentration of about 2×10¹⁷ atoms per cubic centimeter at and within about a thousand angstroms of the upper anode surface 15 results in the forward junction current density J_{S} as indicated by curve B in FIG. 3, with both an adequate forward saturation current density and a reverse current density J_{R}, indicated by curve A, that does not greatly increase as the reverse junction bias voltage V_{R} (see upper horizontal axis) increases beyond approximately 1.5 volts. In Equation 4, the saturation current density J_{S} is what is obtained as an intercept of the Y-axis by an extrapolated forward bias curve line, drawn through the log(J)-V characteristic points where the current curve is linear (i.e., between 0.1 volt to 0.15 volt of curve B or curve D).

For a deep and “flat” a dopant concentration profile as illustrated in FIG. 2B (and contrary to the previously mentioned surface dopant spike region 24 type dopant concentration profile) the reverse current density J_{R} increases sharply with reverse bias voltage, as illustrated by curve C in FIG. 3. This has the effect of robbing power from the very low amount of DC power obtained by the detecting and rectifying of the received RF signal by Schottky diode 10A.

For a surface dopant spike type of profile (illustrated by 28B in FIG. 2A) created by region 24, the curve B in FIG. 3 representing the forward current density J_{F} in Schottky diode 10A levels off due to the series resistance R_{S} at a lower current density than the forward current characteristics represented by curve D measured from a Schottky diode in which the anode has a “flat” profile type as illustrated in increased dopant region 25 in FIG. 2B. This is because a surface dopant spike region 24 type of profile as indicated by curve section 28B in FIG. 2A causes the anode region 18 to be less conductive than the profile type illustrated in increased dopant region 25.

Curve D in FIG. 3 shows that a Schottky diode with an increased “flat” anode surface dopant concentration as indicated by curve part 25 in the profile of FIG. 2B attains about the same saturation current density J_{S} (see the left vertical axis) at a near-zero value of forward bias voltage V_{F} as a Schottky diode with a surface dopant spike concentration profile indicated by curve section 40 of the dopant concentration profile in FIG. 2A). At high forward bias voltages (V_{F}>0.3 volt) the curve D in FIG. 3 saturates at much higher current density J_{F} than curve B due to significantly lower series resistance R_{S}, at the expense of the much higher reverse bias current density J_{R} illustrated by the reverse current density curve C. In a Schottky diode with a narrow anode surface Spike doping concentration profile as indicated by curve section 24 in FIG. 2A, the surface dopant spike region 24 in FIG. 1A fully depletes once the reverse bias voltage reaches around 1 volt, in the case of measured current density curve A in FIG. 3. Under increasing reverse bias voltages, after the surface dopant spike region 24 becomes fully depleted of majority carriers, any further increase in reverse voltage does not significantly increase the electric field at the silicide/silicon interface, and the barrier lowering ΔΦ_{B} also stops increasing and thus the reverse current density J_{R} (see the right vertical axis) increases, and the reverse current density J_{R} levels off as indicated by curve A.

This is not the case in a Schottky diode with the “flat” type anode profile shown in increased dopant region 25. In this case the high concentration of dopant in increased dopant region 25 in FIG. 2B continues depleting, which results in increasing electric field E at the silicide/silicon interface of the anode region 18. Increasing electric field E results in more barrier height lowering ΔΦ_{B} and thus in subsequently increasing reverse current density J_{R} with increasing reverse bias voltage. Note that in the case wherein the surface dopant spike concentration profile of curve and section 25 of FIG. 2A is present in region 24 is present, higher series resistance R_{S} and lower reverse current density J_{R} are traded off for lower series resistance R_{S} caused by a less resistive path between the cathode and anode terminals of an anode having a “flat” deeper increased dopant concentration profile as shown in section 25 in FIG. 2B. The basic Schottky diode structure that includes the surface dopant spike region 24 (FIG. 1B) with the surface dopant spike profile indicated by curve section 24 in FIG. 2A allows an increase in the forward saturation current density J_{S} without significant increase in the reverse current density J_{R} as the reverse bias voltage is increased, at the expense of higher series resistance R_{S} than is produced in increased dopant region 25 by the dope concentration profile indicated by curve section 25 in FIG. 2B. (It should be appreciated that the example of the dopant concentration profile section 25 in FIG. 2B, which was generated using a combination of readily available process profiles that turned out to be satisfactory, is not perfectly “flat”. However, dopant concentration profile section 25 could be generated to have a, more perfectly flat shape.)

The present invention is an improvement of the deep submicron Schottky diodes which are disclosed in the commonly assigned co-pending patent application entitled “Schottky Diode with Minimal Vertical Current Flow” by the present inventor Vladimir F. Drobny and by Derek W. Robinson, docket number TI-39343, Ser. No. 11/174,190, filed Jul. 1, 2005, and incorporated herein by reference. The foregoing co-pending patent application discloses a Schottky diode similar to above described in Schottky diode 10A having a lateral current flow, for integration into various deep submicron integrated circuit fabrication processes. The present invention also is an improvement of an optimized anode dopant profile for Schottky diodes, especially in RFID applications, as shown in another commonly assigned co-pending patent application entitled “Spike Implanted Schottky Diode” by the present inventor Vladimir F. Drobny and Derek W. Robinson, docket number TI-39344, Ser. No. 11/173,695, filed Jul. 1, 2005, and also incorporated herein by reference. The latter co-pending application discloses a Schottky diode including a surface dopant spike region similar to above described in surface dopant spike region 24.

Since filing the two above mentioned co-pending applications, I have discovered that if Schottky barrier diodes described therein are integrated using the deep submicron CMOS processes of which I am aware, intrinsic, parasitic NPM transistors that are formed along with and in parallel relationship to the Schottky diodes may be turned on under certain subsequently described conditions, and that sharply increases the reverse current I_{R} measured from the Schottky diodes as the reverse bias voltage is increased beyond roughly 1.2 to roughly 1.5 volts.

For example, FIG. 4 shows the cathode current of a Schottky diode 10A in FIG. 1A as a function of both their forward bias voltage and reverse bias voltage, both with N-well region 16 electrically floating and also with N-well region 16 connected to the anode region 18, at ground potential. The solid-line curve labeled E_{F},E_{R}, including both forward current section E_{F} and reverse current section E_{R}, is shown for the case when N-well region 16 is connected to ground along with anode region 18. In that case, the terminal current-voltage measurements for the Schottky diodes 10A show very high reverse leakage current (which is so dramatic that it could be mistaken to be a breakdown current) as their reverse bias voltage increases beyond roughly 1.2 volts to roughly 1.5 volts. However, the curve labeled F_{F},E_{R} (defined by the small triangular data points in FIG. 4), including both forward current section F_{F} and reverse current section F_{R}, does not have this undesirable characteristic if N-well region 16 is electrically floating or sufficiently reverse biased with respect to the anode region 18.

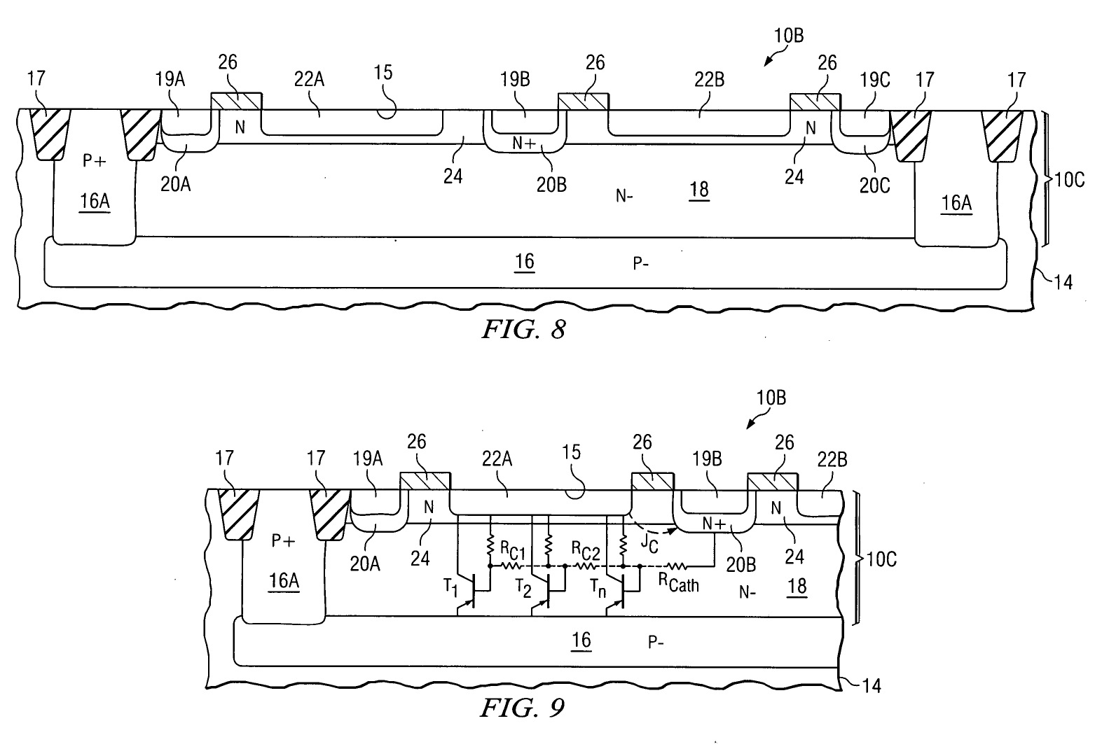

The present invention addresses a method used for suppression of the effects of the above mentioned parasitic NPM transistor on the reverse biased leakage current I_{R} and associated premature breakdown voltage indicated by curve section E_{R} in FIG. 4. This parasitic NPM transistor always exists in lateral Schottky diode 10A, but the effects of the parasitic NPM transistor can be suppressed by sufficiently high doping of the deep “bulk” portion of an anode region in a PM (i.e., P-type-silicon/metal silicide) Schottky diode. (And similarly, the effects of a parasitic PNM transistor as shown in subsequently described FIGS. 8 and 9 can be suppressed by sufficiently high doping in the deep “bulk” portion of a cathode region of a NM (i.e., N-type silicon/metal silicide) Schottky diode.)

Note that the Schottky diode current-voltage characteristics shown in FIG. 3, i.e., curves F_{F} and F_{R}, were measured with the N-well isolation region 16 electrically floating, wherein the total N-well isolation region is composed of N+ sidewall region 16A and “buried” N-well region 16. This prevents the above-mentioned parasitic NPM transistor from turning on if N-well isolation region 16,16A is electrically floating or sufficiently reversed biased with respect to the anode region 18. However, if N-well isolation region 16 is connected (for example, by the conductive connection 13 shown in FIG. 1A) to anode region 18 through the anode contact 19A,B,C, this results in a significant increase in the reverse current I_{R} of a Schottky diode having surface dopant spike region 24 having the dopant concentration profile section 24 of FIG. 2A present. The way the above-mentioned parasitic NPM transistor causes this unexpected increase in the measured reverse bias current I_{R} of Schottky diode 10A is discussed next.

FIG. 4 shows forward and reverse current-voltage characteristics of Schottky diode 10A having the surface dopant spike concentration profile 24 as shown in FIG. 2A, both for the case in which N-type isolation region 16,16A is connected to ground and for the case in which N-type isolation region 16, 16A is left electrically floating. Curve sections E_{F} and F_{F} in FIG. 4 show that under forward bias conditions (i.e., V_{CATHODE}=0 to −1.0 volts), the current-voltage curves of the Schottky diodes 10A are identical for both cases (i.e., floating N-well isolation region 16,16A and N-well isolation region 16,16A electrically connected to the P− anode region 18 at ground voltage).

Under reverse bias conditions with N-well isolation region 16,16A electrically floating, the reverse current I_{R} is normal (i.e. as expected based on Schottky diode theory), as indicated by curve segment F_{R}. However, if N-well isolation region 16,16A is connected to the same potential as anode region 18, the Schottky diode reverse current I_{R} increases dramatically at reverse bias voltages exceeding roughly 1.5 volts, as indicated by the reverse current segment E_{R}. (Note that a Schottky diode having a “flat” high or increased surface doping concentration profile section 25 as shown in FIG. 2B does not exhibit sharply increased reverse current I_{R} in the manner indicated by the current segment E_{R} in FIG. 4.

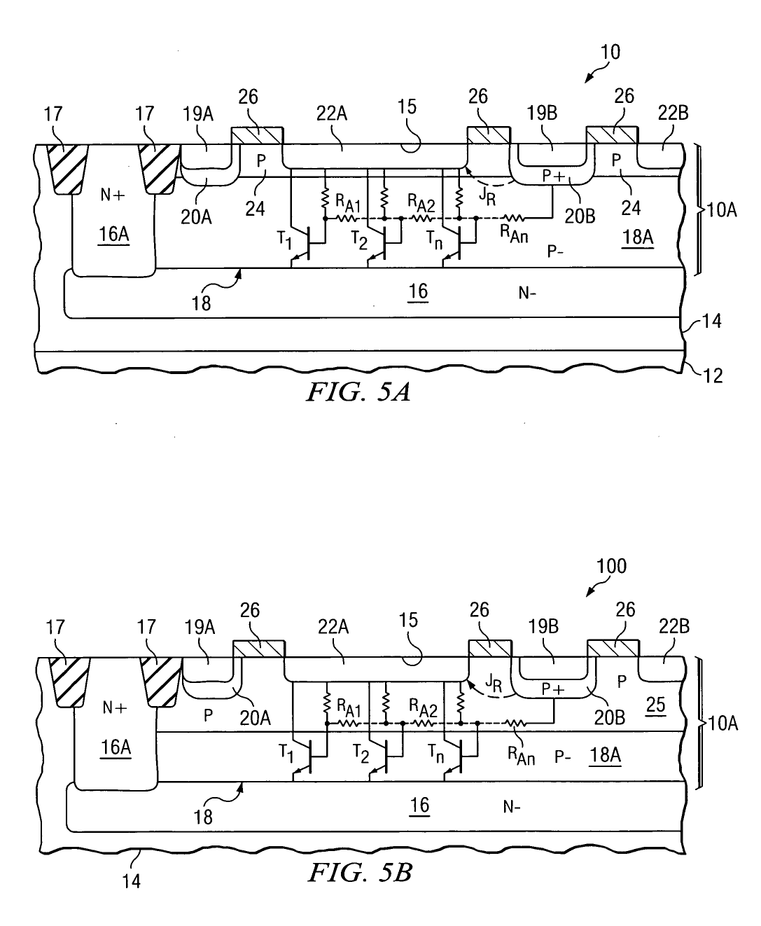

The cross section diagram shown in FIG. 5A repeats the structure shown in FIG. 1A, along with an illustration of the above mentioned intrinsic, distributed parasitic NPM transistor T1,2, 3 . . . n, wherein the buried N-well diffused region 16 forms the emitter, P− anode region 18 forms the base, and the CoSi₂ cathode 22A,B forms the collector.

FIG. 5B includes the same structure as FIG. 5A and further includes the increased dopant region 25 of FIG. 1B within the upper 1 micron portion of anode region 18 immediately below a surface 15. A surface dopant spike region such as 24 of FIG. 1A can be thought of as being included within the top approximately 1000 angstroms of increased dopant region 25, and is included in order to provide an acceptably high value of saturation current density J_{S}. The doping concentration profile in increased dopant region 25 is the raised or “flat” increased dopant concentration section also designated by the same reference 25 in FIG. 2B, and the doping concentration profile in spike the dopant region 24 is the peak dopant concentration section, again designated by the same reference 24 in FIG. 2A.

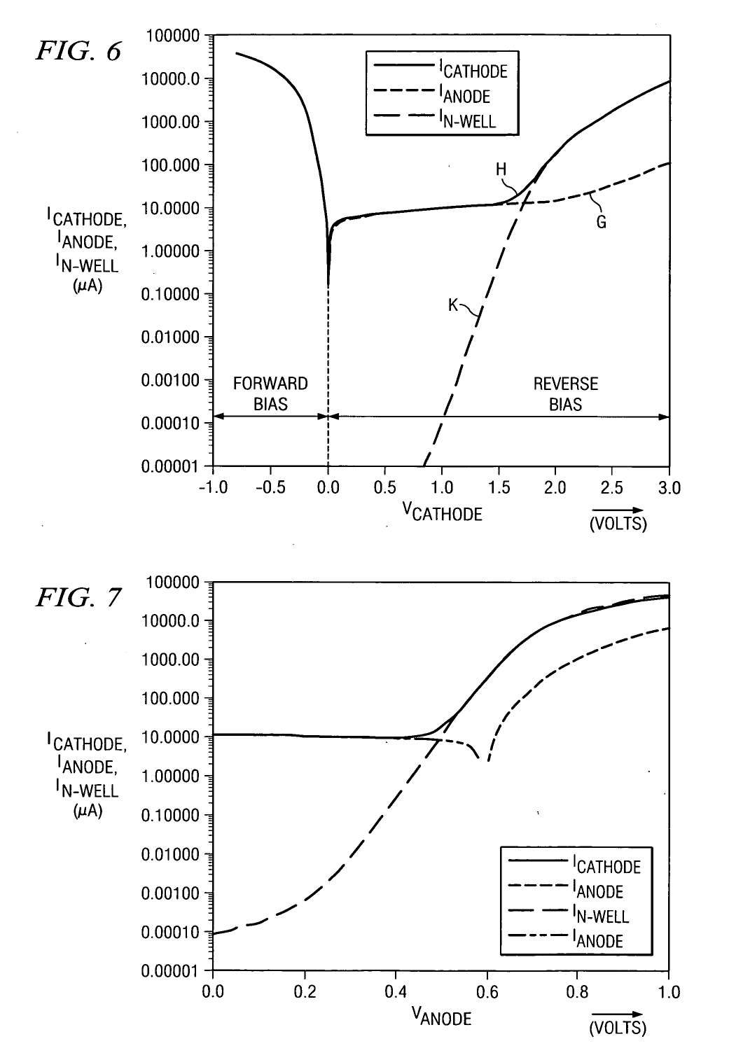

The functionality of parasitic NPM transistor T1,2 . . . n in FIG. 5A, with the N-well isolation region 16 electrically connected to P− anode region 16, was confirmed by measurements of the Schottky diode terminal current, i.e., I_{CATHODE}, I_{ANODE} (which is the collector current of the NPM transistor), and also the current I_{NWELL} (which is the emitter current of parasitic NPM transistor T1,2 . . . n) as shown in FIG. 6. For values of cathode bias voltage V_{CATHODE} exceeding approximately 1 volt, the reverse bias current I_{R} through the cathode 22A in FIG. 5A generates sufficient voltage drop across the distributed resistances R_{A,12 . . . n} in P− anode region 18 to be able to forward bias the NP junction between N-well region 16 and anode region 18, which also is the emitter/base junction of parasitic NPM transistor T 1,2 . . . n, and thereby turn the parasitic NPM transistor on. This is demonstrated by the sudden large increase in the N-well “emitter” current indicated by curve section K and the Schottky cathode/NPM emitter current indicated by curve section H in FIG. 6 as the NPM transistor turns on. The latter is also accompanied by the sudden increase in P− anode base current indicated by curve section G.

If N-well 16 is electrically connected to CoSi₂ anode contact region 19A,B in FIG. 5A, the reverse current through the Schottky diode 10A includes both I_{R} of the Schottky diode junction and the collector current of parasitic NPM transistor T1,2 . . . n and is increased significantly if the anode doping concentration profile of FIG. 2A is used instead of the one shown in FIG. 2B. The increased measured reverse terminal current for reverse bias voltages greater than approximately 1.5 volts if the N-well region 16 is electrically connected to the same potential as the P− anode region 18, is illustrated by the curve section E_{R} in FIG. 4. However, if N-well 16 is left electrically floating, then the measured reverse bias current through the Schottky barrier terminals does not sharply increase in this manner, and instead has the values indicated by curve section F_{R} in FIG. 4.

Thus, the increase in the reverse current leakage represented by segment E_{R} in FIG. 4 is caused by the turning on of the above mentioned parasitic NPM transistor with its base formed by the P− anode region 18. The current gain β of the parasitic NPM transistor T1,2 . . . n, with its base as the more lightly doped portion 18A (see curve section 18 in FIG. 2A) of anode region 18, is much higher than if parasitic NPM transistor T1,2 . . . n has its base in the increased dopant region 25 of FIG. 1B (with the “flat” increased anode doping concentration profile section 25 therein) as shown in FIG. 2B.

In accordance with the present invention, the higher doping concentration in a surface dopant spike region (such as 24) which is actually included within the upper 1000 angstroms of increased dopant region 25 in FIG. 1B and the lower bulk dopant concentration in increased dopant region 25 of anode region 18 are carefully balanced so as to obtain the needed low series resistance R_{S}, high forward saturation current density J_{S}, and an acceptably low reverse current density J_{R}. The dopant concentration in the increased dopant region 25 of anode region 18 in FIG. 1B needs to be high enough to lower the current gain β enough to suppress the operation of the internal NPM parasitic transistor T1,2 . . . n shown in FIG. 5B. Also, increasing of the dopant concentration in the increased dopant region 25 of anode region 18 lowers the distributed resistance R_{A1,2 . . . n} associated with NPM parasitic transistor T1,2 . . . n, and thereby tends to reduce the voltage drop originating from a reverse current J_{R} flowing through the distributed resistance R_{A1,2 . . . n} which tends to reduce the ability of parasitic transistor NPM T1,2 . . . n to be turned on by the reverse current I_{R} of Schottky diode 10A in FIG. 1B.

Since the intrinsic barrier height for the CoSi₂ to P-doped silicon interface is not sufficiently low to provide the saturation current density J_{S} required for Schottky diode 10A to generate enough DC power to operate the RFID tag chip, the additional lowering of the barrier height Φ_{B} needs to be achieved through doping. The relationship between J_{S} and the effective barrier height Φ_{B} is best illustrated by previously described Equations 2 and 4.

The sharp spike of the dopant concentration in the shallow surface dopant spike region (such as 24) that is included in increased dopant region 25 in FIG. 1B just at and within the approximately 1000 angstroms immediately below the silicon/silicide interface causes an increase in the saturation current density J_{S} and also causes some decrease in the series resistance R_{S}. Under increasing reverse bias voltage, the majority carriers in dopant spike region 24 are quickly depleted without significant further increase in electric field E in dopant spike region 24. As a result, the reverse current density J_{R} increases only very slowly with further increase in the reverse bias voltage. The dopant that is distributed deeper into the increased dopant region 25 which has a “flat” increased dopant concentration profile section 25 as illustrated in FIG. 2B further decreases the series resistance R_{S}, and may result in the saturation current density J_{S} being equal to the current density J_{S} due to the surface dopant spike concentration in that region under near-zero bias conditions if the surface concentrations are equal at the surface anode silicon/silicide interface in both dopant cases. Since the majority carriers contributed by this dopant will continue to be depleted as the reverse bias voltage is increased, the electric field E at the surface 15 of the anode silicon 18 will continue increasing, and the barrier lowering term ΔΦ_{B} will continue increasing, resulting in further increase in the reverse current density J_{R}.

If the integrated dopant concentration of the base of the parasitic NPM transistor (referred routinely to as a base Gummel number in the language of bipolar junction transistor physics), i.e., the open concentration of the increased dopant region 25 of P− anode region 18, is too low, then the parasitic NPM transistor will have a current gain β much higher than unity and this will cause the parasitic NPM transistor to conduct a significant amount of current between its emitter and collector in parallel with, and therefore adding to, the reverse current I_{R} of the Schottky diode 10A in FIG. 1A or FIG. 1B once it is turned on. The current gain β of the parasitic NPM (or PNM) transistor 10B in FIG. 1B is decreased by increasing the doping concentration in increased dopant region 25 (acting as the base of the parasitic NPM transistor) doping concentration. Preferably, the current gain β of parasitic transistor T1,2 . . . n is less than a value of roughly 1, in order to make the contribution of the collector current of parasitic transistor T1,2 . . . n negligible compared to the reverse current I_{R} of Schottky diode 10A. Note that increase in the integrated base doping (also referred to as the base Gummel number) increases the conductivity of this region and thus reduces the voltage drop across this “base” region. With reduced self-biasing of this base region, the ability of the emitter-base junction to be turned on diminishes rapidly, thereby making the parasitic NPM transistor T1,2 . . . n inactive.

In order to obtain low-barrier Schottky diode operation suitable for use in RFID tag chips, the above mentioned required Schottky diode characteristics were obtained by providing and testing J_{S}, R_{S} and J_{R} for various combinations of the dopant distribution profiles for the surface dopant spike region (such as 24 in FIG. 2A) and the dopant distribution profile further into increased dopant region 25 in FIG. 1B. Additional information was also obtained by means of simulations performed using the TCAD (Technology Computer Aided Design) tools.

To summarize, suppression of the operation of the parasitic NPM transistors in the described embodiments of the invention is achieved by providing sufficiently high dopant levels in the increased dopant region 25 of the anode region 18 to diminish the current gain P of the intrinsic parasitic NPM (or PNM) parasitic transistors enough that the increasing of the measured reverse junction current represented by segment E_{R} in FIG. 4 is essentially eliminated. The relatively uniform doping concentration in the “flat” section 25 in the dopant concentration profile of FIG. 2B provided in increased dopant region 25 of anode region 18 in FIGS. 1B and 5B is selected to have a sufficiently high level, in the range of 1×10¹⁷ to 2×10¹⁸ atoms per cubic centimeter, so as to not only provide the needed low series resistance R_{S}, but to also adequately diminish or “kill” the current gain β of the parasitic NPM transistor. The peak dopant concentration in the surface dopant spike region (such as 24 in FIG. 2A) portion of increased dopant region 25 is selected to be in the range from 1×10¹⁷to 3×10¹⁷ atoms per cubic centimeter in order to provide a sufficiently high value of saturation current density J_{S} that Schottky diode 10A in FIGS. 1B and 5B can generate a desired amount of DC power by rectifying the measured RF signal. Note that the dopant concentrations referred to herein are approximate, and in other applications these numbers can be varied as required by different thickness of the CMOS well regions measured from the surface of the silicon to the surface of the deep N-well isolation layer 16. In the case of a Schottky diode made by silicide forming an anode over a N-type doped cathode silicon substrate, the values of the concentrations can be adjusted. TCAD simulations give good first order values for initial dopant concentrations.

FIG. 7 shows results of measurement from a Schottky diode where the diode terminals were biased to directly measure the parasitic NPM transistor Gummel plot characteristics as they would be measured if this device were intended to be a primary bipolar transistor. The measurements of Gummel Plot characteristics are routinely used in characterization of a bipolar transistor in evaluation of its current gain and the ideality of the base and collector currents and associated current leakages. The measurements were performed by biasing the Schottky cathode (functioning as the collector of a NPM transistor) to +1.0 volt, which is a lower voltage than a value at which the premature breakdown of the Schottky diode was first observed in FIG. 6 with N-well 16 and the anode terminals 19A,B,20A,B electrically connected together. The common N-well 16 and anode region 18 (equivalent to the emitter and base in the parasitic NPM transistor) voltage than was swept from 0.0 volts to +1.0 volt with the N-well 16 (NPM emitter), anode 18 (NPM base) and cathode 22A,B (NPM collector) currents being measured. The results, equivalent to a Gummel plot of a NPN transistor, were plotted in FIG. 7. These results, once the emitter-base junction was turned on, were used to provide Gummel plots equivalent to those of a bipolar NPN transistor having a current gain of approximately 25-30 near a V_{BE} value of approximately 0.7 volts, as would be easily recognized by those skilled in the art. These measurements can be used to estimate whether or not the functionality of the parasitic NPM transistor T1,2 . . . n is sufficiently suppressed. In the case of the Schottky diode measured to produce the curves shown in FIG. 7, the operation of the parasitic NPM transistor clearly was not adequately suppressed.

As previously mentioned, the prior art describes NPM and PNM transistors but is focused on enhancing their operation as functional bipolar transistors, rather than operating its NM or PM junction as an intrinsic Schottky diode primary device. This is opposite to the present invention associated with a Schottky barrier diode as a primary device in which the NPM or PNM transistors are undesirable parasitic devices and the objective is to prevent them from operating.

It should be appreciated that although the described embodiments of the invention, in which the current gain of the parasitic NPM or PNM transistors is suppressed to prevent them from being turned on and adding to the reverse current of the Schottky diode, are directed to low-barrier Schottky diodes suitable for use in RFID tag chip applications, the described techniques are also useful in other applications, including applications in which high barriers Φ_{B} are required.

FIG. 8 shows a cross sectional diagram of an integrated circuit junction-isolated lateral unguarded Schottky barrier diode similar to the one shown in FIG. 1A. However, the conductivity types of the N-type and P-type regions are reversed. The Schottky diode 10C includes—cathode region 18 formed in buried P-well 16, N+ anode contact region 20A,B, a N-type surface dopant spike region 24, and a silicide anode 22A,B. FIG. 9 shows the same structure, with the distributed parasitic PNM transistor T1,2 . . . n formed in cathode region 18. An N-type “increased dopant region” such as 25 in FIGS. 1B and 5B, including dopant spike region 24, can be readily provided so as to suppress the operation of the parasitic PNM transistor.

While the invention has been described with reference to several particular embodiments thereof, those skilled in the art will be able to make various modifications to the described embodiments of the invention without departing from its true spirit and scope. It is intended that all elements or steps which are insubstantially different from those recited in the claims but perform substantially the same functions, respectively, in substantially the same way to achieve the same result as what is claimed are within the scope of the invention.

What is claimed is:

1. A Schottky diode comprising:
(a) an isolation region of a first conductivity type;
(b) a first electrode region of a second conductivity type isolated by the isolation region, the first electrode region including
i. a relatively lightly doped deep first electrode region of the second conductivity type, and
ii. an increased dopant region of the second conductivity type, the increased dopant region including a shallow surface dopant spike region of the second conductivity type at a surface of the first electrode region, the increased dopant region, including the shallow surface dopant spike region, being more heavily doped than the deep first electrode region;
(c) a heavily doped first electrode contact region of the second conductivity type at the surface of the first electrode region;
(d) a metal silicide second electrode region at the surface of the first electrode region and disposed in the surface dopant spike region, the first electrode region being one of an anode region and a cathode region, the second electrode region being the other of the anode region and the cathode region; and
(e) wherein the surface dopant spike region has a sufficiently high peak dopant concentration to provide a saturation current density that has at least a first predetermined value, and wherein the increased dopant region of the first electrode region has a sufficiently high dopant concentration to cause a current gain of a parasitic bipolar transistor to be less than a second predetermined value and to cause a series resistance to have at least a third predetermined value, the isolation region, the first electrode region, and the metal silicide second electrode region forming an emitter, a base, and a collector, respectively, of the parasitic bipolar transistor.

2. The Schottky diode of claim 1 wherein the increased dopant region has a dopant concentration sufficiently high to reduce the current gain of the parasitic bipolar transistor enough to cause collector current of the parasitic bipolar transistor to be less than a predetermined proportion of a reverse current of the Schottky diode if the isolation region is at the same potential as the first electrode region.

3. The Schottky diode of claim 1 wherein the heavily doped first electrode contact region extends through the surface dopant spike region.

4. The Schottky diode of claim 1 including a metal silicide first electrode contact region disposed in the heavily doped first electrode contact region.

5. The Schottky diode of claim 1 wherein the increased dopant region extends from the surface of the first electrode region approximately 1 micron into the first electrode region to the deep first electrode region, and wherein the surface dopant spike region extends from the surface of the first electrode region approximately 1000 angstroms units into the increased dopant region.

6. The Schottky diode of claim 2 wherein the first conductivity type is N-type and the second conductivity type is P-type.

7. The Schottky diode of claim 2 wherein the first conductivity type is P-type and the second conductivity type is N-type.

8. The Schottky diode of claim 6 wherein the metal silicide is cobalt silicide.

9. The Schottky diode of claim 6 wherein the isolation region includes a lightly doped region adjacent to a bottom of the first electrode region and a heavily doped sidewall region surrounding a side portion of the first electrode region and extending from the surface of the first electrode region to the lightly doped region of the isolation region.

10. The Schottky diode of claim 2 wherein the first electrode region is electrically connected to the isolation region.

11. The Schottky diode of claim 2 wherein the first electrode region is not electrically connected to the isolation region.

12. The Schottky diode of claim 6 wherein the peak dopant concentration in the surface dopant spike region is in the range from approximately b 1×10¹⁷ to 3×10¹⁷ atoms per cubic centimeter.

13. The Schottky diode of claim 6 wherein the dopant concentration in the increased dopant region is in a range from approximately 1×10¹⁷ to 2×10¹⁸ atoms per cubic centimeter.

14. The Schottky diode of claim 12 wherein the dopant concentration in the increased dopant region is in a range from approximately 1×10¹⁷ to 2×10¹⁸ atoms per cubic centimeter.

15. A method of forming an integrated circuit Schottky diode, comprising:
(a) forming an isolation region of a first conductivity type;
(b) forming an first electrode region of a second conductivity type, the first electrode region being isolated by the isolation region;
(c) forming an increased dopant region in the first electrode region, the increased dopant region including a shallow surface dopant spike region of the second conductivity type at a surface of the first electrode region;
(d) forming a heavily doped first electrode contact region of the second conductivity type at the surface of the first electrode region;
(e) forming a metal silicide second electrode region disposed in the increased dopant region at the surface of the first electrode region; and
(f) wherein step (c) includes providing the shallow surface dopant spike region of the first electrode region with a peak dopant concentration that provides a saturation current density that has at least a first predetermined value, and wherein the dopant concentration in the increased dopant region causes a current gain of a parasitic bipolar transistor to be less than a predetermined value to suppress operation of the parasitic bipolar transistor, the isolation region, the first electrode region, and the metal silicide second electrode region forming an emitter, a base, and a collector of the parasitic bipolar transistor.

16. The method of claim 15 wherein step (c) includes forming the increased dopant region with a sufficiently high dopant concentration to provide a series resistance that has at least a second predetermined value, and a reverse current density that is less than a third predetermined value.

17. The method of claim 16 wherein the first conductivity is N-type and the second conductivity type is P-type, and wherein the peak dopant concentration in the shallow surface dopant spike region is in the range from approximately 1×10¹⁷to 3×10¹⁷ atoms per cubic centimeter.

18. The Schottky diode of claim 16 wherein the first conductivity is N-type and the second conductivity type is P-type, and wherein the dopant concentration in the increased dopant region is in the range from approximately 1×10¹⁷ to 2×10¹⁸ of that atoms per cubic centimeter.

19. The Schottky diode of claim 17 wherein the dopant concentration in the increased dopant region is in the range from approximately 1×10¹⁷to 2×10¹⁸ atoms per cubic centimeter.

20. A Schottky diode comprising:
(a) an isolation region of a first conductivity type;
(b) an first electrode region of a second conductivity type isolated by the isolation region, the first electrode region including
i. a lightly doped deep first electrode region of the second conductivity type, and
ii. an increased dopant region of the second conductivity type, the increased dopant region including a shallow surface dopant spike region of the second conductivity type at a surface of the first electrode region;
(c) a heavily doped first electrode contact region of the second conductivity type at the surface of the first electrode region;
(d) a metal silicide second electrode region disposed in the surface dopant spike region at the surface of the first electrode region; and
(e) means for providing the shallow surface dopant spike region of the first electrode region with a peak dopant concentration that provides a saturation current density that has at least a first predetermined value, and means for providing the dopant concentration in the increased dopant region so as to cause a current gain of a parasitic bipolar transistor to be less than a predetermined value to suppress operation of the parasitic bipolar transistor, the isolation region, the first electrode region, and the metal silicide second electrode region forming an emitter, a base, and a collector of the parasitic bipolar transistor.
